(19) United States
(12) Patent Application Publication
(10) Pub. No.: US 2002/0084717 A1
(43) Pub. Date: Jul. 4, 2002

(54) OUTPUT VOLTAGE SENSING OF CHARGE MODE AND VOLTAGE MODE ACTUATOR DRIVERS HAVING A CURRENT MIRROR AMPLIFIER TYPE A/B

(76) Inventor: Terence Joseph Murphy, Plano, TX (US)

Correspondence Address: Daniel W. Swayze, Texas Instruments, Incorporated, M/S 3999, P. O. Box 655474, Dallas, TX, 75265, US

(21) Appl. No.: 09/898,555

(22) Filed: Jul. 2, 2001

Related U.S. Application Data
(63) Continuation-in-part of application No. 09/681,695, filed on May 22, 2001.
(60) Provisional application No. 60/258,853, filed on Dec. 28, 2000.

(51) Int. Cl. H01L 41/02

(52) U.S. Cl. 310/311

(57) ABSTRACT

A piezo actuator drive circuit (40) adapted to be sensed in both a charge and voltage mode. The present invention achieves technical advantages as a piezo actuator driver (200) that can be sensed in the charge mode by switching a drive amplifier (42) output to a high impedance state to characterize a load. Preferably, feedback resistors (R₃, R₄) configured as a resistive divide network are used as a sensor feeding an analog-to-digital converter. A DC restore amplifier (44) forming a portion of a closed loop feedback is selectively reconfigured in the sensing mode to an open loop feedback and forms a portion of the sensing circuitry.

### CLAIM OF PRIORITY

This application claims priority from U.S. provisional application Serial No. 60/258,853 entitled “Closed Loop Charge Mode Drive for Piezo Actuators Using DC Restore Amplifiers” filed Dec. 28, 2000.

### CROSS REFERENCE TO RELATED APPLICATIONS

This application is a continuation-in-part of commonly assigned U.S. patent application Ser. No. 09/681,695 entitled “Integrated Charge and Voltage Mode Drive Circuit for Piezo Actuators Used in Mass Data Storage Devices, or the Like”, filed May 22, 2001, the teachings of which are incorporated herein by reference:

### FIELD OF THE INVENTION

The present invention is generally related to the field of mass media information storage devices, and more particularly to a drive circuit and method for using a piezo actuator in both a charge mode and a voltage mode.

### BACKGROUND OF THE INVENTION

Hard disk drives are mass storage devices that include a magnetic storage media, e.g. rotating disks or platters, a spindle motor, read/write heads, an actuator, a pre-amplifier, a read channel, a write channel, a servo circuit, and control circuitry to control the operation of hard disk drive and to properly interface the hard disk drive to a host system or bus. FIG. 1 shows an example of a prior art disk drive mass storage system 10. Disk drive system 10 interfaces with and exchanges data with a host 32 during read and write operations. Disk drive system 10 includes a number of rotating platters 12 mounted on a base 14. The platters 12 are used to store data that is represented as magnetic transitions on the magnetic platters, with each platter 12 coupleable to a head 16 which transfers data to and from a preamplifier 26. The preamp 26 is coupled to a synchronously sampled data (SSD) channel 28 comprising a read channel and a write channel, and a control circuit 30. SSD channel 28 and control circuit 30 are used to process data being read from and written to platters 12, and to control the various operations of disk drive mass storage system 10. Host 32 exchanges digital data with control circuit 30.

Data is stored and retrieved from each side of the magnetic platters 12 by heads 16 which comprise a read head 18 and a write head 20 at the tip thereof. The conventional readhead 18 and writehead 20 comprise magneto-resistive heads adapted to read or write data from/to platters 12 when current is passed through them. Heads 16 are coupled to preamplifier 26 that serves as an interface between read/write heads 18/20 of disk/head assembly 10 and SSD channel 28. The preamp 26 provides amplification to the waveform data signals as needed. A preamp 26 may comprise a single chip containing a reader amplifier 27, a writer amplifier, fault detection circuitry, and a serial port, for example. Alternatively, the preamp 26 may comprise separate components rather than residing on a single chip.

Piezo actuators have improved performance when driven by quantities of charge versus the amount of voltage applied to it. The charge mode drive improves two important areas of performance, both well documented in the literature, namely, effects over temperature, and effects due to hysteresis. To operate a piezo actuator in a charge mode configuration, the drive circuit output must be placed in a high impedance, open loop state. Disadvantageously, once in an high impedance state, the piezo actuator can drift through charge loss, wander due to transducer effects, or simply wander due to a variety of effects and lack of feedback.

Whether the piezo actuator is driven in the voltage mode or the current mode, it is important in systems that use the actuators to sense voltage on the output at a given point in time. This may be for calibration reasons, or simply to understand the current position of the actuator, or even to use the actuator as a sensing device.

There is desired an improved piezo actuator drive circuit that can sense voltage of the piezo actuator at any given time in either the voltage mode or the charge mode, and which provides for a single driver design.

### SUMMARY OF THE INVENTION

The present invention achieves technical advantages as a piezo actuator driver having a piezo actuator that can be sensed in either the voltage mode or the charge mode. Depending on whether the driver is operated in the charge mode or the voltage mode, the resistor feedback is either the voltage mode feedback in the voltage mode, or the resistor feedback for a DC restore amplifier in the charge mode.

The driver circuit is adapted to drive multiple piezo actuators, which number may vary from drive to drive. This circuit advantageously results in a closed loop system having a charge mode operation within a bandpass that can be tuned for desired operation. Below the bandpass turn on the circuit operates in the voltage mode, and the closed loop system restores the piezo output to a defined DC voltage and compensates for any wandering effects. The closed loop system also compensates for any DC current mismatches in the closed loop configuration such that the piezo output is centered around a desired DC operating point.

The present invention advantageously uses a second amplifier with a resistor/capacitor configured as an integrator to set up the DC restore for the piezo driver and produce a highpass response. At high frequencies above the cut on of the loop, the driver is advantageously in a charge mode drive. However, below the cut on frequency, the driver is in a voltage mode and restoring the output to a commanded DC voltage. This circuit is compatible with a voltage mode drive, yet provides a charged mode solution without the conventional drawbacks including wandering output DC voltage. Offsets are compensated by the loop.

### BRIEF DESCRIPTION OF THE DRAWINGS

FIG. 1 illustrates a conventional disk drive system including multiple rotating disks or platters, read/write heads, a piezo actuator, a servo circuit, and associated amplifier and control circuitry;

FIG. 2 depicts a simplified schematic of the piezo drive circuit of the present invention including the DC restore feedback loop;

FIG. 3 is a graph of the AC response and DC response of the piezo actuator drive, the AC response being a function of the AC command signal and the DC response being a function of the DC offset;

FIG. 4 is a detailed schematic of the present invention;

FIG. 5 illustrates that portion of the schematic of FIG. 4 operative during the charge mode operation thereof;

FIG. 6 illustrates that portion of the schematic of FIG. 4 active during the voltage mode operation thereof;

FIG. 7 is a waveform diagram illustrating the transient response of the piezo actuator at both the output OUT1X and output OUT6XP;

FIG. 8 is a waveform depicting the transient response of the piezo actuator when driving 8 elements; and

FIG. 9 is a graphical illustration of the outputs OUT1X and OUT6XP as a function of time for a power up sequence with the DC restore loop being initialized;

FIG. 10 is a schematic of another preferred embodiment allowing sensing of a piezo driver in a voltage mode;

FIG. 11 is a waveform timing diagram illustrating the output waveform during sensing as a function of the load and calibration resistors;

FIG. 12 is a schematic diagram of another preferred embodiment including a driver circuit allowing for sensing of the piezo actuator in the charge mode; and

FIG. 13 is a waveform diagram illustrating the output sensing in the charge mode with a high starting voltage.

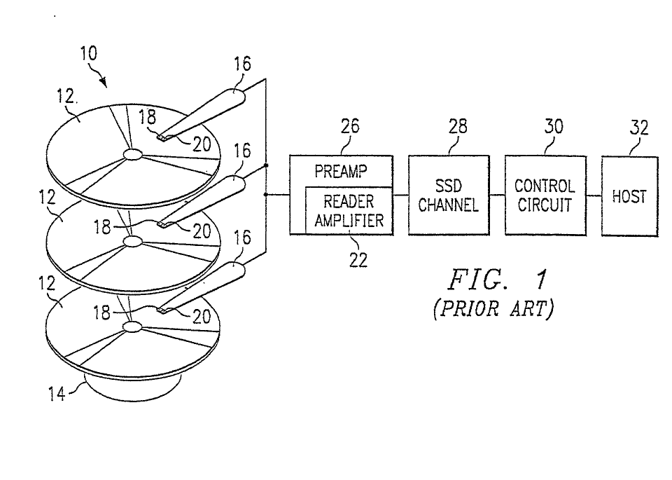

### DETAILED DESCRIPTION OF THE PREFERRED EMBODIMENT AND BEST MODE

Referring now to FIG. 2, there is depicted at 40 a simplified schematic of the present invention seen to comprise a piezo actuator circuit adapted to drive a piezo actuator in both a charge mode and a voltage mode. Circuit 40 is seen to include a differential drive amplifier 42 having an inverting input connected to a voltage reference V_{ref}, and a non-inverting input coupled to and controlled by a AC command signal provided by a digital to analog converter (DAC) as will be discussed shortly. Driver 42 is seen to have a 1X output that is placed at a capacitor shown as C_{piezo}. Driver 42 also has two outputs identified as OUT6XP and OUT6XN coupled to current mirrors based on the currents of the OUT1X output. Each of these two outputs provides current equal to 6.125X the current sent out on the OUT1X output. This will be discussed in more detail shortly.

Circuit 40 is seen to further comprise of a low frequency voltage nulling loop around the charge control driver circuit 42 including an operational amplifier 44. The inverting input of amplifier 44 is coupled to the OUT6XP output, and having its output connected to the non-inverting input of driver 42, as shown. A feedback capacitor C1 is provided such that amplifier 44 is configured as a high frequency integrator. The feedback path from the OUT6XP output to the input of the driver 42 provided through the integrating DC restore amplifier 44 advantageously has the effect to null any DC offsets at the capacitor C_{piezo}. By providing this feedback, the system is overall balanced and the charge mode operation is maintained. The effect of the DC restore feedback removes any DC response from the DAC signal to the piezo output, however, this does not hinder system operation.

As mentioned above, the DC restore feature creates an AC coupled solution from the DAC input to the output OUT6XP, which is also referred to as the piezo drive node. It is also desired to have some control, from a DC coupled standpoint, as to where the OUT6XP output tends to at DC. Advantageously, this is accomplished with another input feature added through the offset DAC into a resistor, shown as the DC offset DAC signal coupled through resistor R2 and summed at the inverting input of amplifier 44. This resistor R2 is connected to the DC restore amplifier and allows for a low frequency DC coupled path and thus allows the DC positioning of the piezo in the charge mode to be changed.

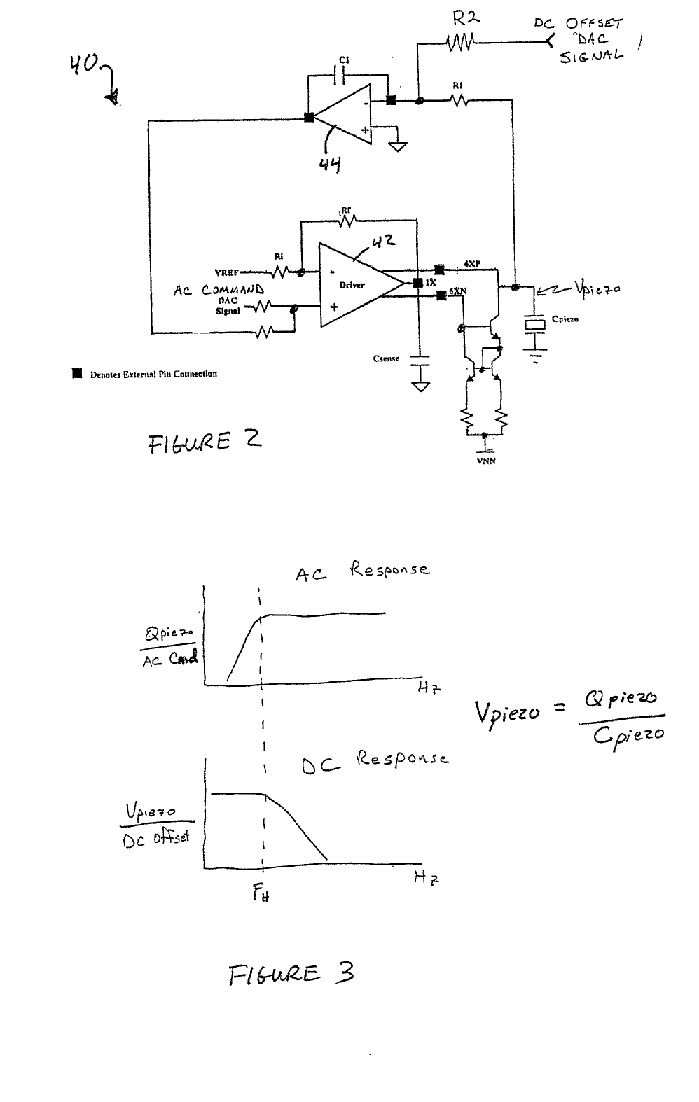

Referring now to FIG. 3, there is depicted both the AC response and DC response of circuit 40. Notably, the AC response is flat above the bandpass frequency Fₕ, yet tapers to 0 below the bandpass frequency. Conversely, the DC response is flat below the bandpass frequency, but tapers off above the bandpass frequency at Fₕ. The AC response curve depicts on the vertical axis the value Q_{piezo}/AC command as a function of frequency. With respect to the DC response, the vertical axis depicts the relationship of V_{piezo}/DC offset as a function of frequency. The following relationship applies;

V_{piezo}=Q_{piezo}÷C_{piezo}

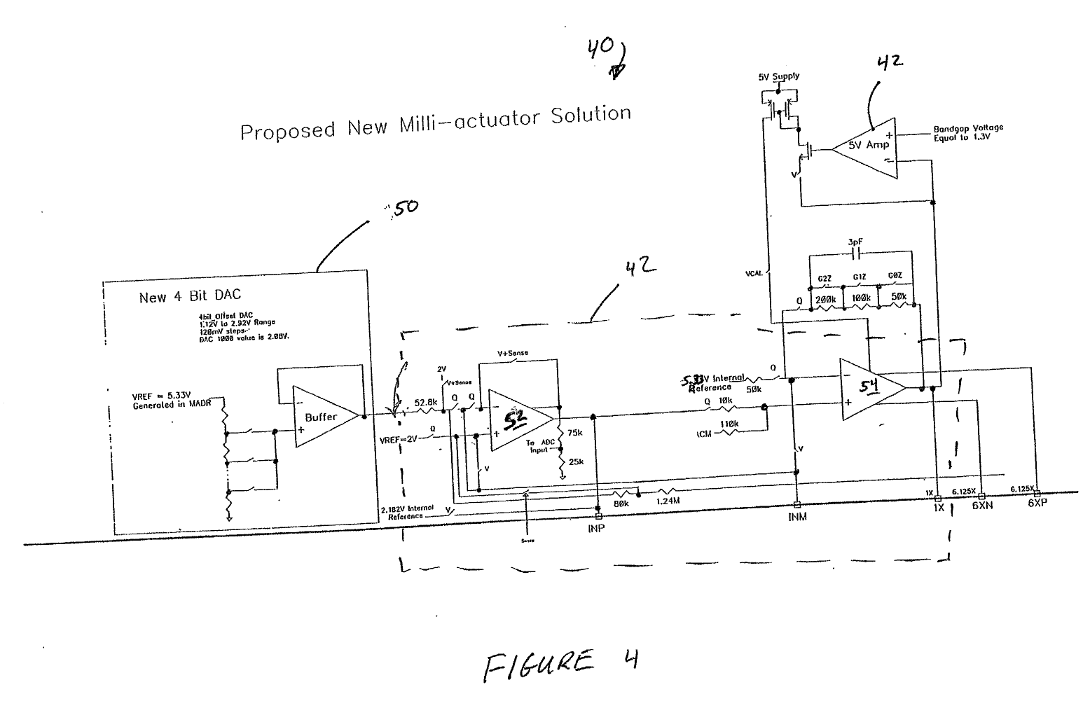

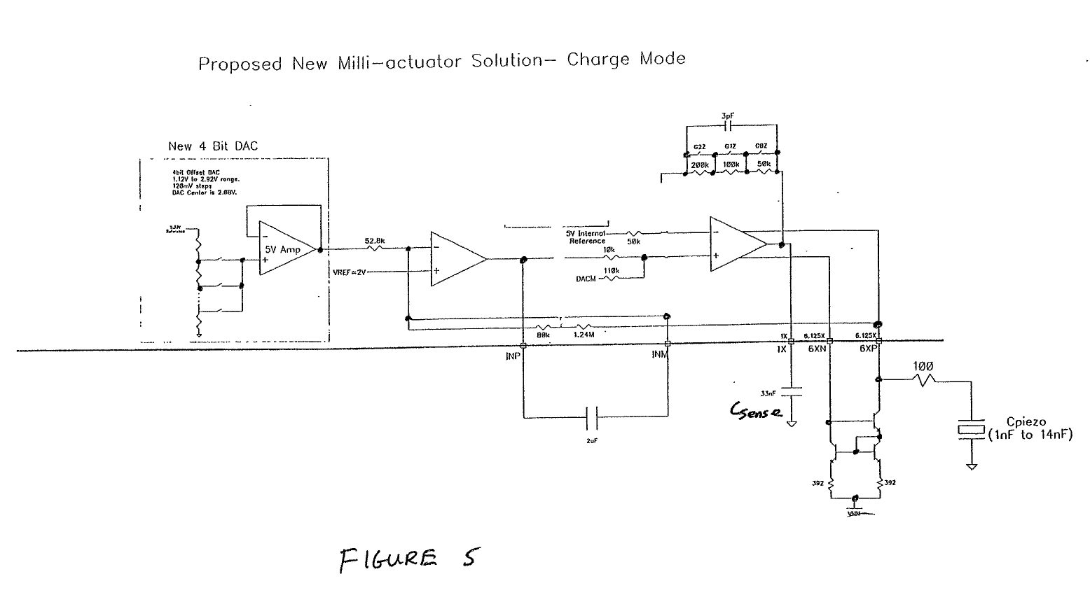

Turning now to FIG. 4, there is depicted a more detailed schematic of circuit 40, whereby the driver 42 is shown as amplifier 54 with feedback selectable by switches. The DC restore amplifier is depicted as amplifier 52 with its feedback and switches that select between charge and voltage mode. A four-bit digital-to-analog converter (DAC) 50 is seen to provide the DC command input to the inverting input as shown.

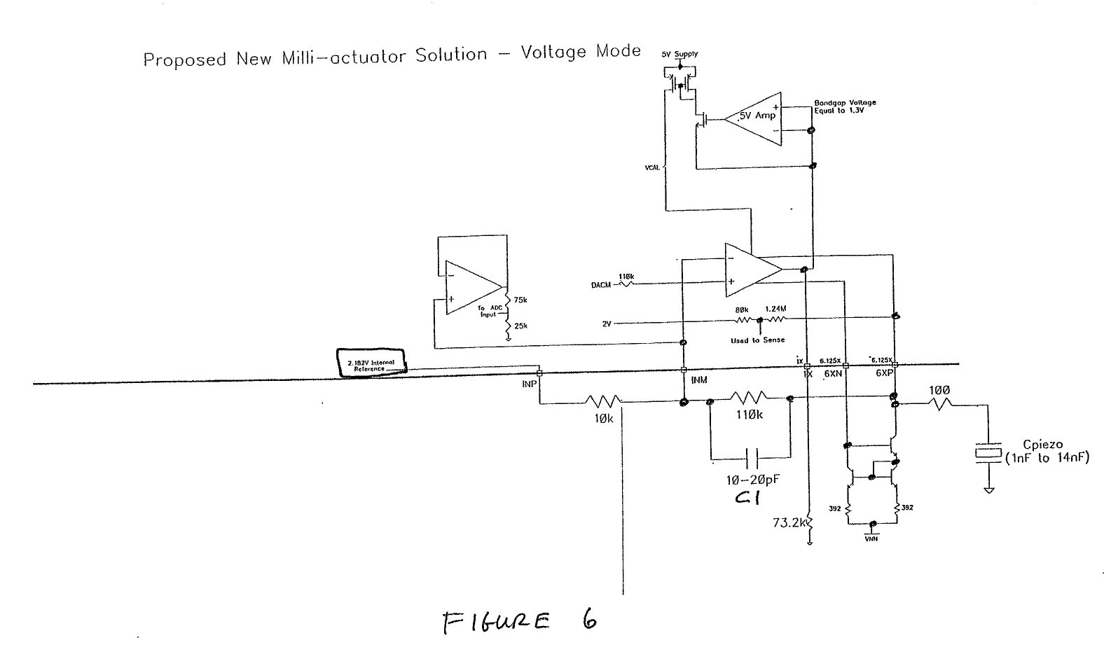

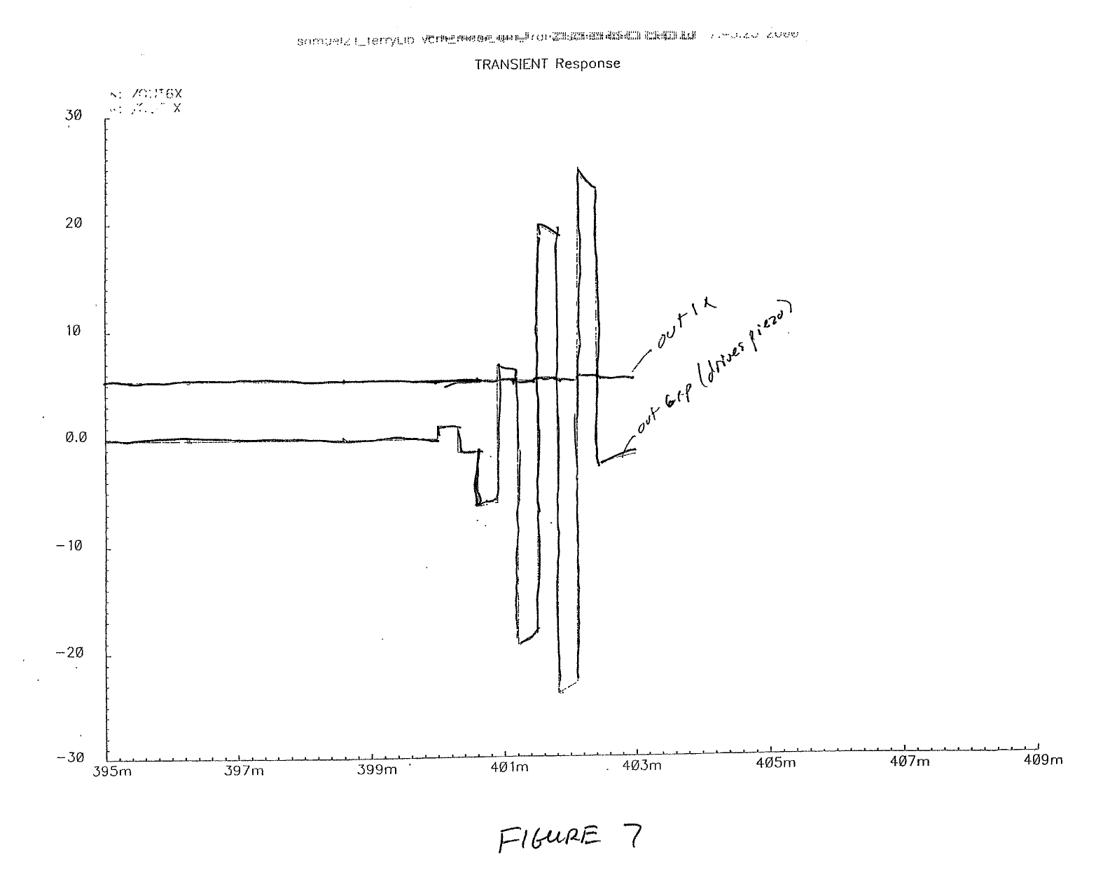

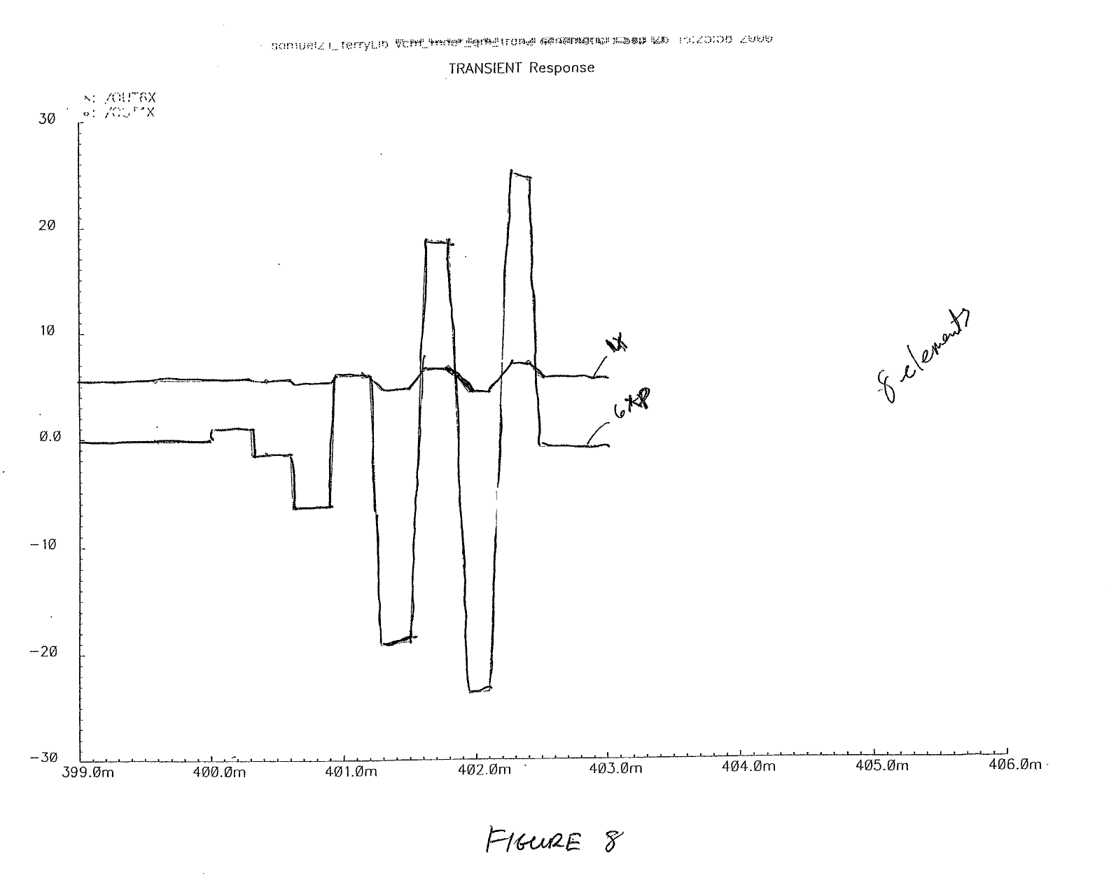

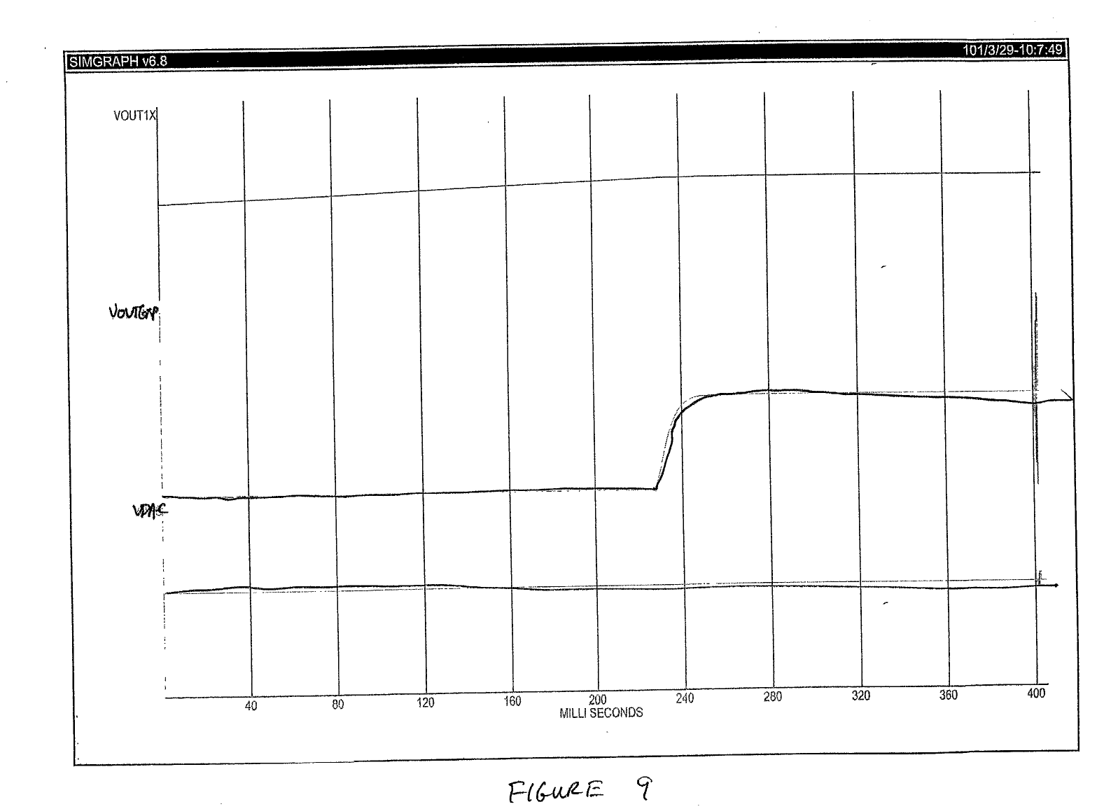

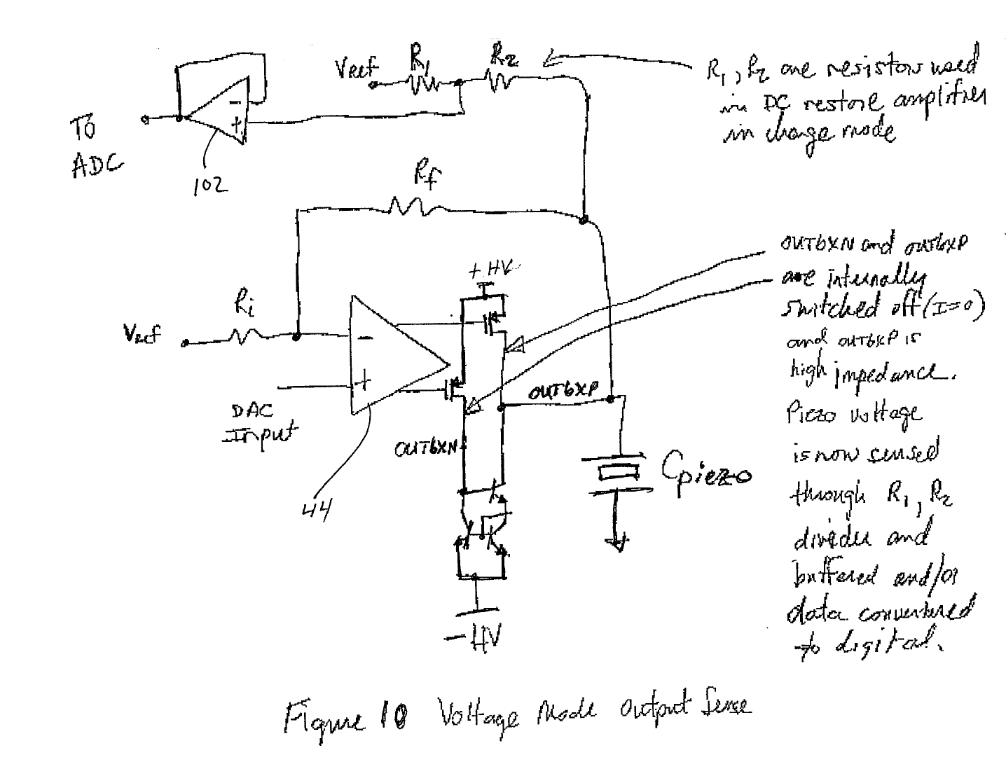

FIG. 5 depicts the active circuitry when the circuit is operating in the charge mode, and FIG. 6 illustrates the active circuitry of circuit 40 when the circuit operates in the voltage mode. Thus, reference to FIGS. 4,5 and 6 is made during the following discussion as to the operation of the present invention.

Circuit 40 provides the ability to program between voltage mode and charge mode operation by changing a MCTRL <3> bit in the serial port which controls a milliactuator signal QVZ. When in the voltage mode, the circuit operates with feedback capacitor C1 provided externally. The offset DAC is not active. The reference amplifier block provides a 2.182 volt bias voltage to the INP pin that is connected to the externally configured feedback. The voltage mode operation does have a calibration mode that is selected using a MCTRL <4> bit in the serial port which enables a milliactuator signal CAL. CAL mode provides a fixed positive current on the output OUT6XP which will charge the piezo capacitor C_{piezo}. The output voltage of the piezo is then sensed using the external resistor feedback network and the REFAMP2 amplifier of the drive block (_DRV). The REFAMP2 blocks output is sent to the ADC of the circuit and the customer has access to the desired piezo output voltage.

In the charge mode, the advantageous features of the milliactuator solution circuit 40 are featured. The features include the charge mode operation being provided for varying number of piezo elements, how the operation is maintained when normal offsets from processing are present, and how a DC coupled input is provided in conjunction with the DC restore operation.

The first advantageous feature is how the charge mode solution allows for a varying number of piezo elements. This is accomplished by setting up a voltage mode feedback on the OUT1X output using the amplifier 42. The feedback is internal to the integrated circuit (IC), but could be provided externally as well. The DAC input is at the input of the amplifier 42 and is gained up through the amplifier feedback and provided to the OUT1X output. A capacitor Cₛₑₙₛₑ is place on the OUT1X output. Based on the voltage swing of the capacitor and the capacitor value, a certain amount of charge is placed in the capacitor Cₛₑₙₛₑ. The OUT6PX and OUT6XN outputs are current mirrors based on the currents of the OUT1LX output. These outputs each provide current equal to 6.125×the current sent out on the OUT1LX signal. Given a certain amount of charge provided to the OUT1X output, 6.125 times this charge is provided to the OUT6XP or OUT6XN outputs depending on whether the charging on OUT1X is positive or negative −, that is, negative charging shows up on OUT6XN and vice versa for OUT6XP. If the load on OUT6XP, which is the main point of interest since the piezo element will be connected there, changes due to a different number of piezo elements used (this is common place for piezo actuator applications where a different number of actuators are being driven depending on the system configuration), then the output charge gain needs to be changed according to the number of piezo elements on the output.

Advantageously, this is accomplished by correspondingly switching the gain of the feedback on OUT1X and thus change the overall charge gain. One important aspect to this is that there are two important time constants that must be matched to keep the overall transfer function matched. The resistor value in the feedback on OUT1X multiplied by the capacitor used on OUT1X must match the output piezo capacitance (total load of all piezo elements used) and the resistance seen on the OUT6XP output. Therefore, the solution for changing the gain on the OUT1LX is done with the overall feedback resistance changing using switches G0Z, G1Z and G2Z such that the RC product on the OUT1X is matched to the changing RC on OUT6XP, which changes with the number of piezo elements,—and this is a key feature also provided by the solution.

The advantageous second feature is how the DC restore amplifier 44 is used to compensate for offsets in the OUT1X/OUT6XP circuit chain. There will be some current mismatch when the amplifier chain is manufactured, and this mismatch could cause the OUT6XP output to saturate into one rail or the other. This would make the solution non-usable and make the charge mode solution useless. To overcome this, a feedback path from the OUT6XP output to the input of the amplifier 42 is provided through the integrating DC restore amplifier 44. The effect of the feedback is to null any DC offsets. By providing this feedback, the system is overall balanced and the charge mode operation is maintained. The effect of the DC restore feedback does remove any DC response from the DAC signal to the piezo output, however, this does not hinder system operation.

The advantageous third feature is the DC coupled input. As mentioned above, the DC restore feature creates an AC coupled solution from DAC input to the OUT6XP output (piezo drive node). It is desired to also have some control, from a DC coupled standpoint, as to where the OUT6XP output tends to at DC. This is accomplished with another input feature added through the offset DAC into a resistor. This resistor R2 is connected to the DC restore amplifier and allows for a low frequency DC coupled path and thus allows the DC positioning of the piezo in charge mode to be changed.

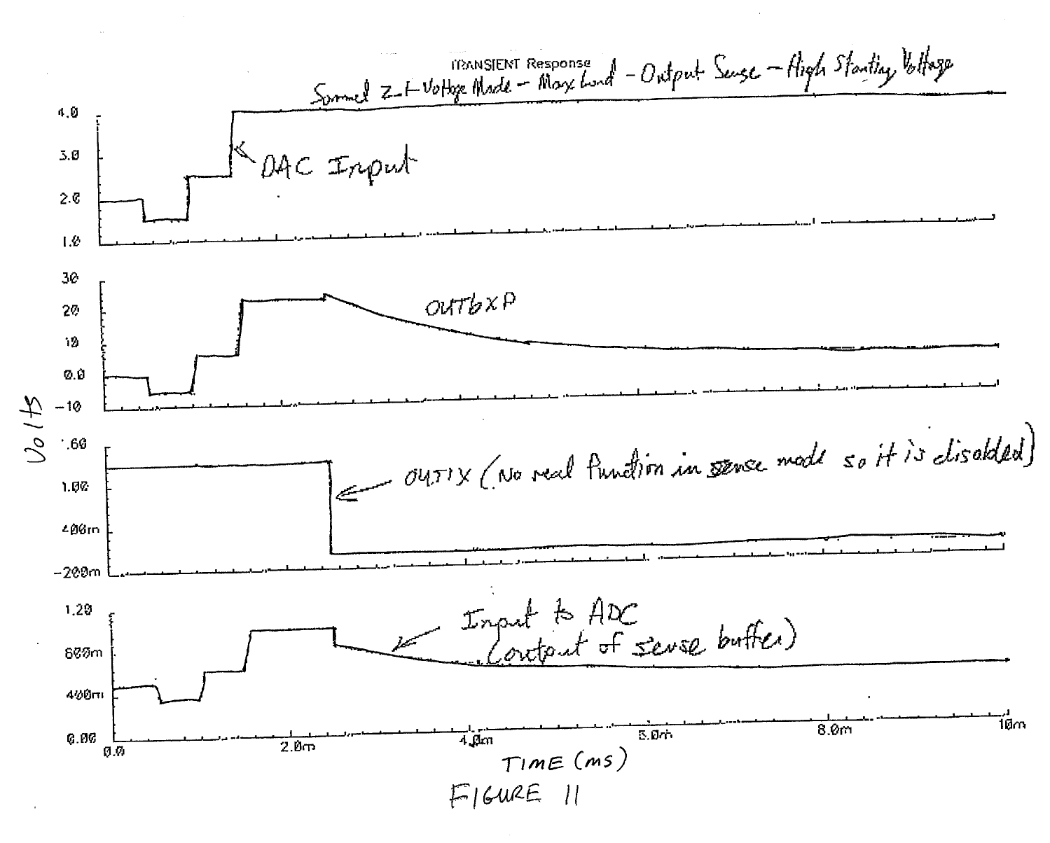

Referring now to FIG. 10, there is generally shown at 100 a piezo actuator drive circuit having a piezo actuator adapted to be sensed in the voltage mode or the charge mode, wherein like numerals to those shown in earlier discussed Figures refer to like elements. The sensing mode of the present invention achieves technical advantages by switching the output of the drive amplifier 42 to a high impedance state, and disconnecting the output mirrors. The sensing can be switched to one or the other output mirror set. A resulting output voltage at the piezo actuator is sensed by a resistive divide network when the drive amplifier has a high impedance state and thus no effect on the resistive divide network. The output sensed voltage from the piezo actuator is used to determine how much the piezo actuator load has varied, and can be used to compensate for previously mentioned unwanted defects. The driver output is sensed using the feedback of the amplifier itself, and is measured using a resistor divider output which is coupled to an analog-to-digital converter (ADC).

Referring to FIG. 10, no current is provided by output OUT6XP or OUT6XN in the sense mode, and the current mirror comprising a Class AB amplifier stage is operationally removed from the piezo actuator using switching FETs. In this sensing mode, the output of the drive amplifier 42 is put into the high impedance mode.

To characterize the piezo actuator C_{piezo} in the sensing mode, the charge on the piezo actuator induces a voltage drop across the resistive divide network shown as resistors R₁ and R₂ forming a portion of the feedback in the voltage mode. The output of this resistive divide network, that is, the node between resistors R₁ and R₂, is provided to a sensing amplifier shown at 102 forming a buffer and subsequently feeding a resistive divide network shown as resistors R₃ and R₄. The output is sensed between resistors R₃ and R₄ and provided to the analog-to-digital converter (ADC). This sensed signal is indicative of the piezo actuator i.e. position and allows the circuit to characterize the changes of the load. These changes can then be compensated for, the previously mentioned undesirable parameters including temperature variation, voltage variation, and hysteresis effects. The present invention advantageously allows a voltage mode driver to be utilized which is simpler and cheaper to use while allowing the use of an existing amplifier design.

It is also noted that the feedback resistor network shown as resistor R_{f} and Rᵢ also form a resistive divider network, whereby a signal indicative of the piezo actuator can be sensed between these resistors similar to that described with regards to the divider network formed of resistors R₁ and R₂. The advantage of using the resistors R₁ and R₂ is that they form a portion of the DC restore network and are coupled to a known voltage reference depicted as V_{ref} and which can also be used in the charge mode.

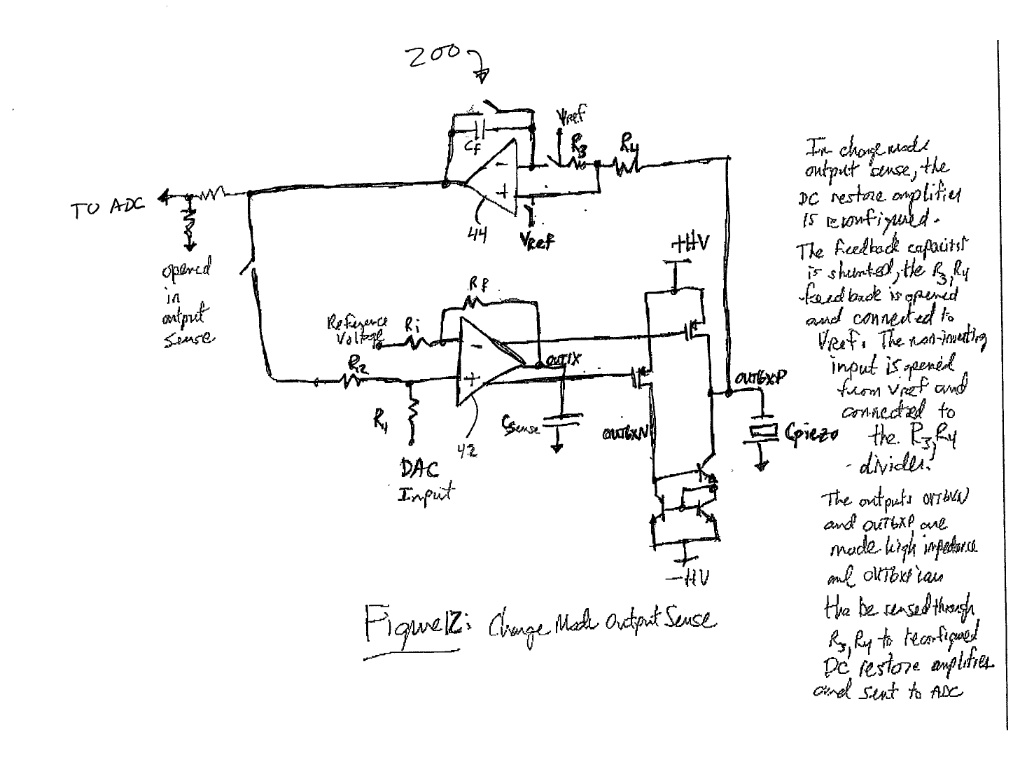

Referring to FIG. 11, there is depicted the DAC input signal at 104, the output OUT6XP signal at 106, and the command signal used in the sensing mode at 108. As shown, the output signal 106 moves as a function of the feedback resistors R_{f}, Rᵢ, R₁ and R₂.

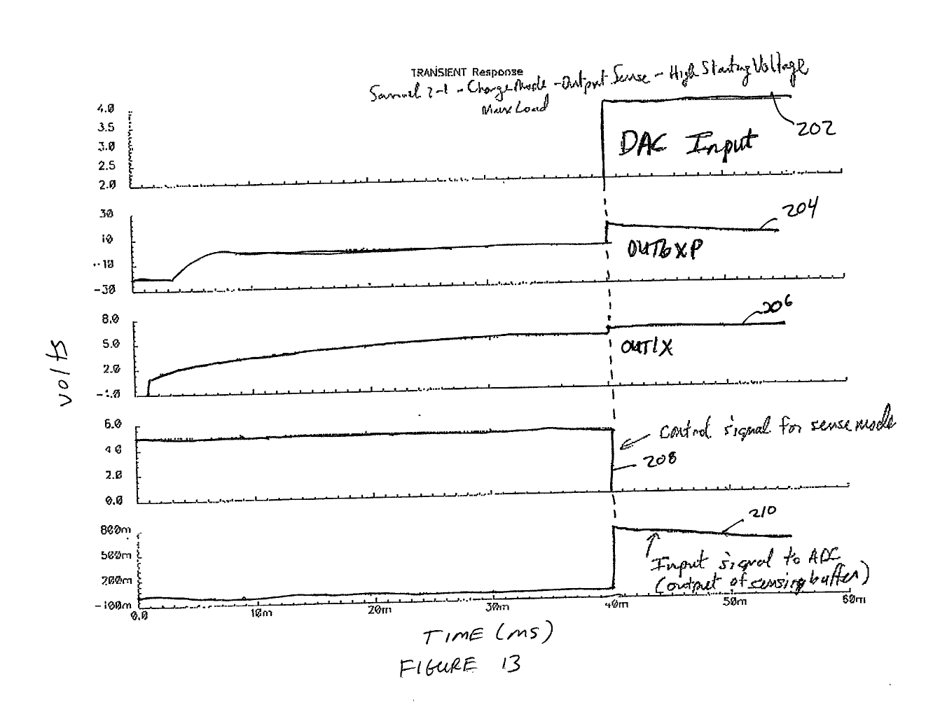

Referring now to FIG. 12, there is depicted at 200 a piezo actuator drive circuit having the capability to sense the piezo actuator in both the charge mode and the voltage mode. In the charge mode, the DC restore amplifier 44 is reconfigured. The feedback capacitor C_{f} is shunted, and the resistors R₃ and R₄ forming the resistive feedback are opened and connected to the voltage reference V_{ref}. The non-inverting input of the DC restore amplifier 44 is opened from voltage V_{ref} and connected to the resistive divide network of resistors R₃ and R₄. The outputs OUT6XN and OUT6XP are made high impedance, and output OUT6XP is sensed through resistors R₃ and R₄ and the reconfigured DC restore amplifier 44. The output from this reconfigured DC restore amplifier 44 is then sent to and sensed by the ADC as shown. The DC restore amplifier forms a portion of a closed loop feedback in the charge mode, and forms a open loop feedback in the calibration mode. Advantageously, the single drive 200 can be used in both modes.

Referring to FIG. 13, there is depicted the DAC input as signal waveform 202. Output OUT6XP is shown at 204, output OUT1X is shown at 206, the control signal for the sense mode is shown at 208, and the input signal for the ADC, which is the output of the sensing buffer, is shown at 210. It is noted that FIG. 13 depicts the signals in the charge mode when sensing the output piezo actuator with a high starting voltage and a maximum load.

The advantage of this solution in voltage mode is that it allows the user to have insight into what the load is doing as a function of time with only the sensing circuitry connected. They can use it for calibration and determination of the size of the load—which they can in turn determine the number of elements (heads) connected.

In charge mode, the output operates with a high impedance characteristic at the output do to the nature of the circuitry. Piezo actuators can also act as transducers that sense movement and they can also be impacted by other disturbances such as EMI. Given that the output is essentially high impedance, the output voltage can wander. The DC restore compensates, but at a low frequency. With the output sense mode, the user can now determine at a higher frequency what the output is doing and compensate if the voltage is shifting outside the desired operating range.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

We claim:

1. A piezo actuator drive circuit, comprising:
a drive amplifier having an input, and an output adapted to drive a piezo actuator in a voltage mode; and
a sensing circuit coupled to the drive amplifier sensing the piezo actuator.

2. The drive circuit as specified in claim 1 wherein the sensing circuit is selectively coupled to the piezo actuator in a voltage mode.

3. The drive circuit as specified in claim 1 wherein the sensing circuit selectively coupled to the piezo actuator in a charge mode.

4. The drive circuit as specified in claim 1 wherein the drive amplifier has a high impedance output in the sensing mode.

5. The drive circuit as specified in claim 4 wherein the sensing circuit provides a signal indicative of the piezo actuator position.

6. The drive circuit as specified in claim 1 wherein the sensing circuit comprises a resistor divider providing a voltage signal.

7. The drive circuit as specified in claim 6 wherein the voltage signal varies proportionally to the piezo actuator load.

8. The drive circuit as specified in claim 1 wherein the drive amplifier has a feedback, wherein the sensing circuit is a portion of the feedback.

9. The drive circuit as specified in claim 5 wherein the signal is indicative of the piezo actuator load variation.

10. The drive circuit as specified in claim 1 further comprising a current mirror selectively coupled to the output of the drive amplifier.

11. The drive circuit as specified in claim 10 wherein the current mirror is selectively uncoupled from the drive amplifier in the sensing mode.

12. The drive circuit as specified in claim 11 wherein the current mirror is a class AB amplifier.

13. The drive circuit as specified in claim 1 wherein the drive amplifier has a charge mode feedback configured to allow multiple piezo actuators to be driven in the charge mode.

14. The drive circuit as specified in claim 13 wherein the charge mode feedback includes a DC restore amplifier forming a portion of the sensing circuitry.

15. The drive circuit as specified in claim 14 wherein the DC restore amplifier is reconfigured in the sensing mode.

16. The drive circuit as specified in claim 15 wherein the reconfigured DC restore amplifier is connected in a closed feedback loop in the charge mode, and in an open feedback loop in the sensing mode.

17. The drive circuit as specified in claim 1 wherein the drive amplifier has a first output, and a second output having a current mirror based on the first output.

18. The drive circuit as specified in claim 17 wherein a capacitor is coupled to the first output and the piezo actuators are adapted to be driven by the second output.

19. The drive circuit as specified in claim 18 wherein a first time constant formed by the capacitor and the voltage mode feedback, and a second time constant formed by the piezo actuators and the voltage mode feedback, are substantially equal.

20. The drive circuit as specified in claim 13 further comprising a DC control circuit controlling the DC value at the piezo actuator.

21. The drive circuit as specified in claim 1 wherein the DC control circuit is integrated into the low frequency compensation loop.

22. The drive circuit as specified in claim 1 further comprising a digital-to-analog (DAC) coupled to one drive amplifier input and a voltage reference being coupled to another drive amplifier input.

23. The drive circuit as specified in claim 1 further comprising an ADC coupled to the sensing circuit.
